(19) United States
(12) Patent Application Publication
(10) Pub. No.: US 2025/0357171 A1
(43) Pub. Date: Nov. 20, 2025

(54) CHUCKING SYSTEM WITH SILANE COUPLING AGENT

(71) Applicant: Lam Research Corporation, Fremont, CA (US)

(72) Inventors: Lin XU, Fremont, CA (US); Satish SRINIVASAN, Newark, CA (US); John DAUGHERTY, Fremont, CA (US); Harmeet SINGH, Fremont, CA (US)

(21) Appl. No.: 18/871,372

(22) PCT Filed: May 31, 2023
(86) PCT No.: PCT/US2023/024038

§ 371 Date: Dec. 3, 2024

Related U.S. Application Data
(60) Provisional application No. 63/350,252, filed on Jun. 8, 2022.

(51) Int. Cl. H01L 21/683; C23C 4/11; C23C 4/12; H01J 37/32

(52) U.S. Cl. CPC H01L 21/6833; C23C 4/11; C23C 4/12; H01J 37/32477; H01J 37/32715; H01J 2237/2007

(57) ABSTRACT

A chuck system for supporting a substrate in a plasma processing chamber is provided. A base plate comprises a substrate support region and a shoulder surrounding the substrate support region. A protective coating is on a surface of the base plate, wherein the protective coating covers at least part of the shoulder. A layer of a silane coupling agent is on the protective coating.

### CROSS-REFERENCE TO RELATED APPLICATION

This application claims the benefit of priority of U.S. Application No. 63/350,252, filed Jun. 8, 2022, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The disclosure relates to a method and apparatus for plasma processing a substrate. More specifically, the disclosure relates to a method and apparatus for providing a chucking system in a plasma processing chamber.

In plasma processing, a plasma processing chamber with a chuck system may comprise an edge ring that is used to provide improved process control. A plasma processing chamber may be used to treat substrates such as semiconductor wafers. Example processes that may be performed on a substrate include but are not limited to, chemical vapor deposition (CVD), atomic layer deposition (ALD), conductor etch, dielectric etch, and/or other etch, deposition, or cleaning processes. A substrate may be arranged on a chuck system such as a pedestal, an electrostatic chuck (ESC), etc. in a processing chamber of the substrate processing system. During etching, etch gas mixtures including one or more gases may be introduced into the processing chamber and plasma may be used to initiate chemical reactions. The chuck system may comprise an edge ring to surround the substrate and improve process uniformity. Various methods may be used to facilitate heat transfer between the edge ring and other parts of the chuck system to further improve process uniformity. Some chuck systems have insufficient heat transfer between the edge ring and the rest of the chuck system causing nonuniformities in the processing of the substrate.

### SUMMARY

To achieve the foregoing and in accordance with the purpose of the present disclosure, a chuck system for supporting a substrate in a plasma processing chamber is provided. A base plate comprises a substrate support region and a shoulder surrounding the substrate support region. A protective coating is on a surface of the base plate, wherein the protective coating covers at least part of the shoulder. A layer of a silane coupling agent is on the protective coating.

In another manifestation, a method for forming a substrate support for use in a plasma processing chamber is provided. A base plate is provided with a substrate support region and a shoulder surrounding the substrate support region. A protective coating thermal is sprayed on a surface of the base plate, wherein the protective coating covers at least part of the shoulder. A layer of a silane coupling agent is deposited on the protective coating.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic cross-sectional view of a plasma processing chamber with an embodiment.

FIG. 2 is a high level flow chart that may be used in some embodiments.

FIGS. 3A-F is an enlarged view of part of an electrostatic chuck system, shown in FIG. 1, that may be used in some embodiments.

FIGS. 4A-C illustrate chemical reactions for silane coupling agents and silicones that may be used in some embodiments.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

In some plasma processing systems, an edge ring is placed to surround a substrate being processed. The edge ring is used to improve processing uniformity. Temperature control of the edge ring is important for processing uniformity. As higher aspect ratio features are sought after, the bias applied to a substrate increases. The higher bias increases the heating of the edge ring, requiring increased temperature control of the edge ring. An increase in thermal contact between the edge ring and temperature control devices, such as a chuck is required. In order to provide uniformity, an ESC may be conditioned/seasoned several times by applying a gel between an edge ring and ESC and then providing a plasma for on the order of 50 RF hours and then replacing the gel and edge ring. Such chamber conditioning is time consuming and reduces the output of a plasma processing chamber. Reducing the amount of time required for chamber conditioning increases chamber output and lowers the cost of ownership.

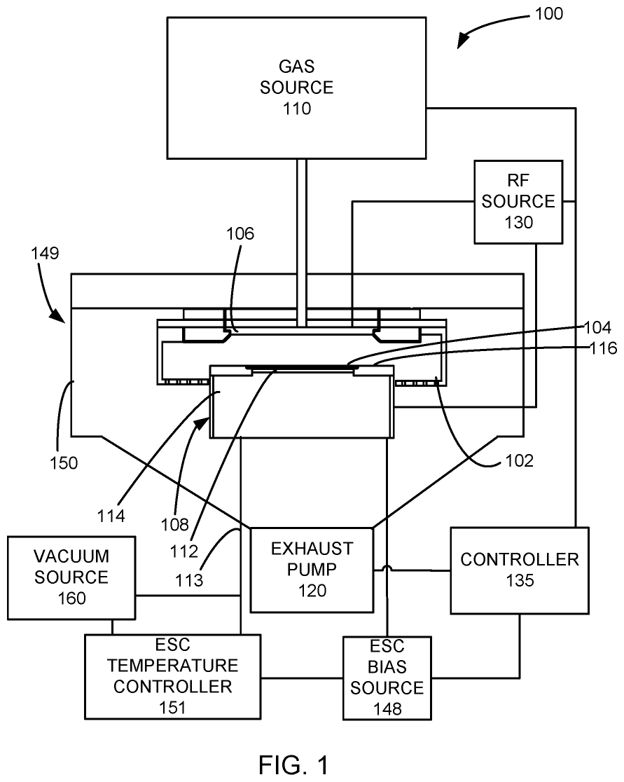

To facilitate understanding, FIG. 1 is a schematic view of a plasma processing chamber that may be used in some embodiments. In one or more embodiments, the plasma processing system 100 comprises a gas distribution plate 106 providing a gas inlet and a chuck system 108 comprising a ceramic plate 112 and a base plate 114, within a plasma processing chamber 149, enclosed by a chamber wall 150. Within the plasma processing chamber 149, a substrate 104 is positioned on top of the chuck system 108 so that the chuck system 108 acts as a substrate support within the plasma processing chamber 149. The chuck system 108 may provide a bias from the electrostatic chuck (ESC) bias source 148 to provide an electrostatic chuck system. A gas source 110 is connected to the plasma processing chamber 149 through the gas distribution plate 106. An ESC temperature controller 151 is connected to the chuck system 108 and provides temperature control of the chuck system 108. A vacuum source 160 is connected to the chuck system 108. A radio frequency (RF) source 130 provides RF power to chuck system 108 and an upper electrode, which in some embodiments is the gas distribution plate 106. In some embodiments, 400 kilohertz (kHz), 2 megahertz (MHz), 60 MHz, and optionally, 27 MHz power sources make up the RF source 130. In some embodiments, one generator is provided for each frequency. In some embodiments, the generators may be in separate RF sources or separate RF generators may be connected to different electrodes. For example, the upper electrode may have inner and outer electrodes connected to different RF sources. Other arrangements of RF sources and electrodes may be used in other embodiments, such as in another embodiment the upper electrodes may be grounded.

A controller 135 is controllably connected to the RF source 130, the ESC bias source 148, an exhaust pump 120, and the gas source 110. An edge ring 116 forms part of the chuck system 108 and surrounds the outer edge of the substrate 104. An example of such a plasma processing chamber is the Exelan Flex™ etch system manufactured by Lam Research Corporation of Fremont, CA. The process chamber can be a CCP (capacitively coupled plasma) reactor or an ICP (inductively coupled plasma) reactor or maybe another type of powered plasma in various embodiments.

In some embodiments, a gel is placed between the edge ring 116 and the base plate 114 of the chuck system 108. The gel would be used to transfer heat from the edge ring 116 to the base plate 114. In some embodiments, the gel would have a high thermal conductivity, have a sufficiently high mechanical strength, have good adhesion to the base plate 114, should be easy to apply, be resistant to plasma erosion, provide little contamination, and have a low cost of replacement. Gels formed from silicones meet many of these characteristics. Silicones provide thermal stability with a proper viscosity in a temperature range of about −80° C. to 250° C. Silicones are acceptably resistant to UV and oxidation damage. Silicones are flexible, having a low Young's modulus. In some embodiments, the Young's modulus is in the range of 50 kPa to 2000 kPa. In some embodiments, the Young's modulus is in the range of 100 kPa to 1000 kPa. In some embodiments, the gel layer is formed from a low molecular weight in the range of 10,000 to 100,000 grams/mole silicone with a low cross-linking density. If the cross-linking is too dense the gel layer would be not flexible enough to accommodate imperfections in the surfaces of the edge ring 116 and base plate 114. Fillers may be added to the silicone in order to tune the thermal conductivity. In some embodiments, the filler is aluminum oxide particles. In other embodiments, the filler comprises at least one of boron nitride particles and carbon fibers. In some embodiments, the filler is a dielectric material. In some embodiments, the dielectric filler material may be used for capacitive RF coupling. In some embodiments, the filler is electrically conductive. In some embodiments, the electrically conductive filler may be used to electrically conduct a direct current (DC) bias. In some embodiments, the filler is etch resistant, does not become a contaminant, has a high thermal conductivity, and is easy to disperse in the gel. With an increasing plasma power, a higher thermal conductivity is needed for the gel, requiring a higher filler content. The higher filler content reduces the flexibility of the gel and also reduces the adhesion of the gel. The reduced adhesion of the gel may cause delamination of the gel, causing issues with thermal transfer from the edge ring. Gel adhesion is critical for effective thermal transfer from the edge ring.

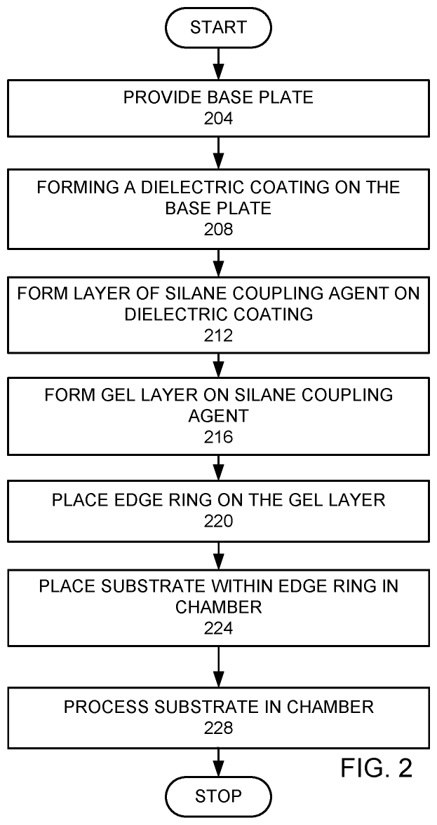

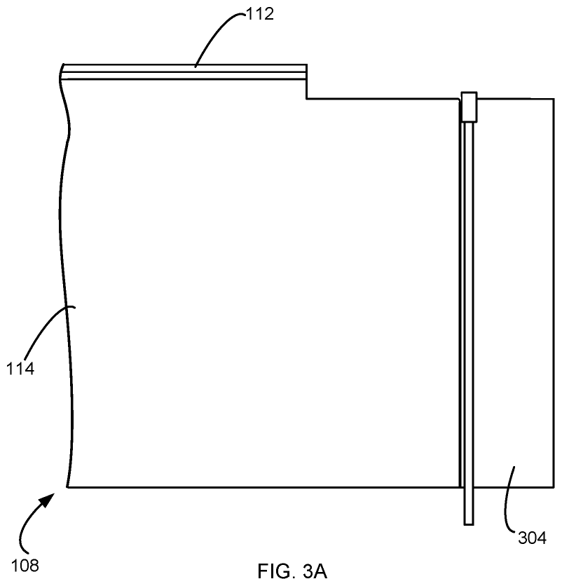

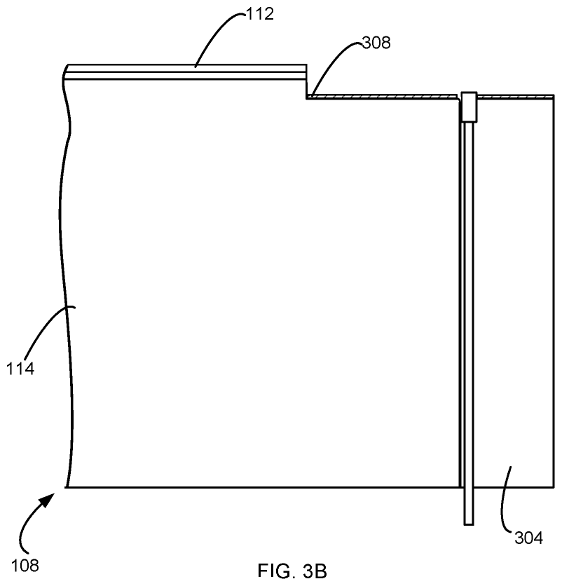

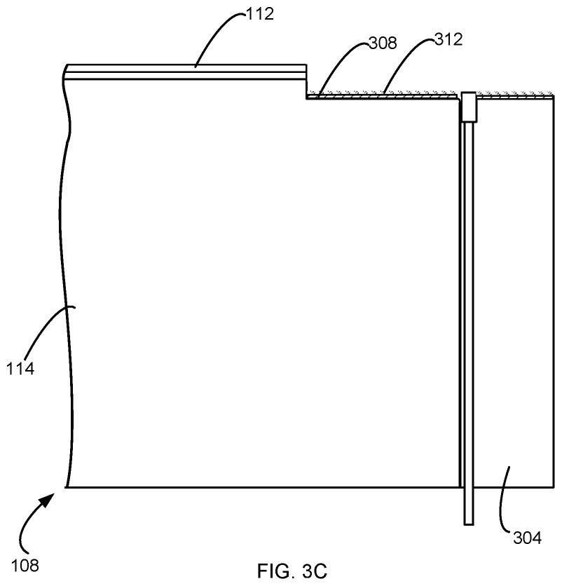

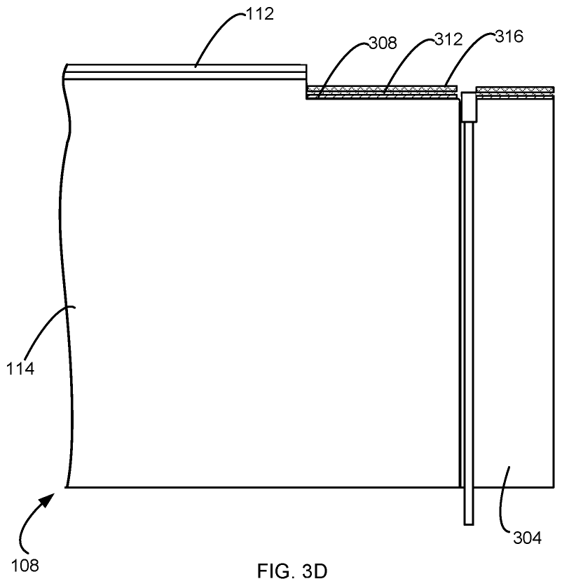

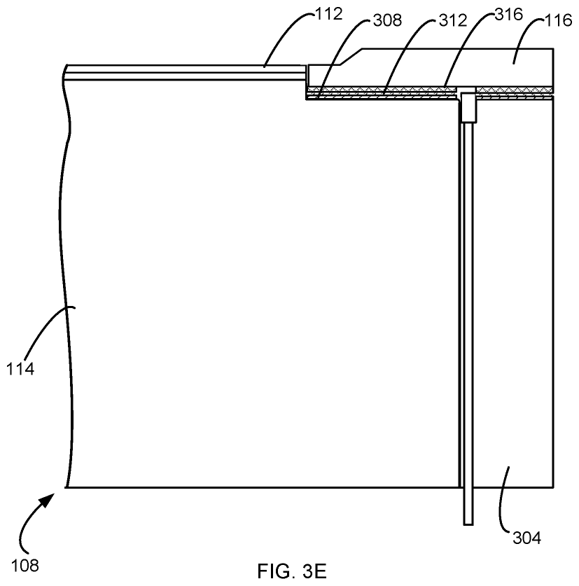

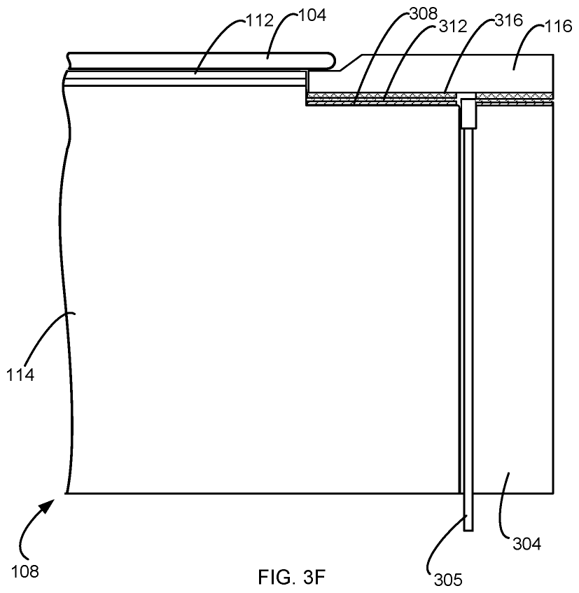

FIG. 2 is a flow chart of a process for providing a chuck system used in some embodiments. A base plate is provided (step 204). FIG. 3A is an enlarged view of part of a base plate 114 and ceramic plate 112 of a chuck system 108 that may be used in some embodiments of the apparatus shown in FIG. 1. In some embodiments, a tunable edge sheath (TES) ring 304 is placed around the base plate 114.

A dielectric coating is formed on the base plate 114 (step 208). In some embodiments, the dielectric coating is a metal oxide or metal oxide containing coating, such as aluminum oxide. In some embodiments, the metal oxide coating is a thermal spray coating, such as a plasma spray coating deposited using a plasma spray. Plasma spraying is a type of thermal spraying in which a torch is formed by applying an electrical potential between two electrodes, leading to the ionization of an accelerated gas (a plasma). Torches of this type can readily reach temperatures of thousands of degrees Celsius, liquefying high melting point materials such as ceramics. Particles are injected into the jet, melted, and then accelerated towards a surface so that the molten or plasticized material coats the surface of the component and cools, forming a solid, conformal coating. Various embodiments may use various spraying processes, such as at least one of thermal spray processes such as wire arc spraying, air plasma spraying, atmospheric plasma spraying, suspension plasma spraying, low-pressure plasma spraying, and very low-pressure plasma spraying. Other spraying processes may be cold spraying, kinetic energy spraying, and aerosol deposition. FIG. 3B is an enlarged view of part of a base plate 114 of a chuck system 108 after a dielectric coating 308 has been deposited on the base plate 114 and a top of the TES ring 304. In some embodiments, the base plate 114 has a lower portion forming a shoulder on which the edge ring will be placed surrounding a substrate support region of the base plate 114. In some embodiments, the dielectric coating 308 is formed on top of the shoulder of the base plate 114. The dielectric coating 308 is not drawn to scale in order to more easily illustrate the dielectric coating 308. In some embodiments, the thickness of the dielectric coating is in the range of 100 μm to 1000 μm.

A layer of a silane coupling agent is formed on the dielectric coating 308 (step 212). In some embodiments, the silane coupling agent has a molecular form of R—(CH₂)—Si(X₃), where R is an organofunctional group and at least one X is hydrolyzable for forming a reactive silanol group. In some embodiments, R is an epoxy or amine that is compatible with silicone. In some embodiments, at least one X is OH, for example, the coupling agent could be R—(CH₂)—Si(OH)(CH₃)₂. At least one X is hydrolyzable and is able to react with an OH bond of the dielectric coating. R is an organofunctional group that cross-links with silicone. FIG. 3C is an enlarged view of part of the base plate 114 of a chuck system 108 after a layer of a silane coupling agent 312 is formed on the dielectric coating 308. In some embodiments, the layer of the silane coupling agent 312 has a thickness in the range from a monolayer to 100 nm. In some embodiments, the layer of the silane coupling agent 312 has a thickness in the range from a monolayer to 10 nm. In some embodiments, the thickness of the layer of silane coupling agent 312 has a thickness that is able to increase adhesion preventing the separation of a gel layer under thermal stress conditions, without affecting thermal coupling and electrical coupling. In some embodiments, the dielectric coating 308 is porous. The layer of silane coupling agent 312 is thick enough to penetrate into the pores of the dielectric coating 308 in order to prevent the creation of voids and in order to increase the adhesion of the layer of silane coupling agent 312 to the dielectric coating 308. In some embodiments, two coatings are used to provide the layer of silane coupling agent.

A gel layer is formed on the layer of silane coupling agent 312 (step 216). In some embodiments, the gel layer comprises silicone gel. Silicone gel is a polymer made up of siloxane, where siloxane has the molecular form of —R₂Si—O—SiR₂—, where R is an organic group. In order to provide an increased thermal conductivity, the gel layer further comprises a filler. In some embodiments, the filler comprises at least one of aluminum oxide particles, boron nitride particles, and carbon fibers. In some embodiments, the filler material comprises a range of 5% to 70% by weight of the total gel. In some embodiments, the filler material comprises a range of 20% to 60% by weight of the total gel. In some embodiments, the filler material comprises a range of 40% to 50% by weight of the total gel. In some embodiments, the gel layer has a thickness in the range of 50 μm to 1000 μm. In some embodiments, the gel layer has a thickness in the range of 100 μm to 1000 μm. In some embodiments, the gel layer has a thickness in the range of 350 μm to 500 μm. FIG. 3D is an enlarged view of part of the base plate 114 of a chuck system 108 after a layer of a gel layer 316 is formed on the silane coupling agent 312.

An edge ring 116 is placed on the gel layer 316 (step 220). FIG. 3E is an enlarged view of the chuck system 108 after the edge ring 116 is placed on the gel layer 316. A substrate is placed within the edge ring 116 in a chamber. FIG. 3F is an enlarged view of the chuck system 108 with a substrate 104 placed within the edge ring 116. The substrate 104 is processed in the chamber. The processed substrate 104 may be removed and replaced with another substrate so that a plurality of substrates may be processed. In some embodiments, a fluid connection 305 provides coolant from the ESC temperature controller 151 to a backside of the edge ring 116.

In some embodiments, the edge of the substrate 104 extends over part of the edge ring 116. In some embodiments, the edge ring 116 is used to provide a flat plasma sheath in order to provide more uniform processing of the substrate 104. The TES ring 304 provides an electrostatic tuning in order to provide a flat or tuned plasma sheath. In some embodiments, the electrical coupling between the base plate 114 and the substrate matches the electrical coupling between the base plate 114 and the edge ring 116 in order to provide a flat plasma sheath. In addition, in some embodiments, to provide a more uniform process, the edge ring 116 must be cooled. In some embodiments, a gel layer 316 provides a high thermal conductivity in order to allow heat from the edge ring 116 to be transferred to the base plate 114. In some embodiments, the TES ring 304 provides electrical control of the edge ring 116. In some embodiments, the gel layer 316 is a dielectric gel. In some embodiments, the gel layer 316 is thin, so that as the temperature changes, the gel layer 316 may delaminate from the base plate 114. In some embodiments, the base plate 114 may be cooled to 15° C. In some embodiments, the TES ring 304 provides more cooling than the base plate 114 by providing more temperature control than the temperature control provided to the base plate 114. In some embodiments, a temperature sensor is provided in the TES ring 304.

In some embodiments, the use of an elastic gel increases the thermal coupling between the edge ring 116 and the base plate 114, and TES ring 304. Since the filler is more thermally conductive than the elastic gel, to improve thermal control more filler is needed. Too much filler makes the gel too weak. In some embodiments, the gel layer 316 is kept thin to provide a more consistent and stronger capacitive coupling and a higher thermal conductivity. In some embodiments, as the edge ring 116 is heated through a temperature range, a mismatch in the materials used to form the edge ring 116, base plate 114, and TES ring 304 increases shear stress at gel layer 316 surfaces that might cause separation of the gel layer 316. The increased adhesion provided by some embodiments prevents the gel layer 316 from separating in thermal stress conditions.

In some embodiments, since the silicone gel has a low cross-linking density, the silicone gel is able to bind to the silane coupling agent 312. In some embodiments, the layer of silane coupling agent 312 is applied to an oxidized aluminum coating over the base plate 114. In some embodiments, the gel layer 316 is removed before or during the wet clean, but the silane coupling agent 312 is not removed. In such embodiments, a new gel layer is deposited, but the silane coupling agent 312 does not need to be reapplied. In some embodiments, the gel layer 316 and the layer of silane coupling agent 312 are able to survive a wet clean, so that the gel layer 316 and layer of silane coupling agent 312 do not need to be reapplied after a wet clean in order to avoid requiring recalibration and conditioning after each wet clean. In addition, removal of the gel layer 316 may be difficult if the gel layer 316 is absorbed into the pores of the dielectric coating 308. In addition, the gel layer 316 may only be partially removed so that reapplication of the gel layer 316 causes nonuniform results.

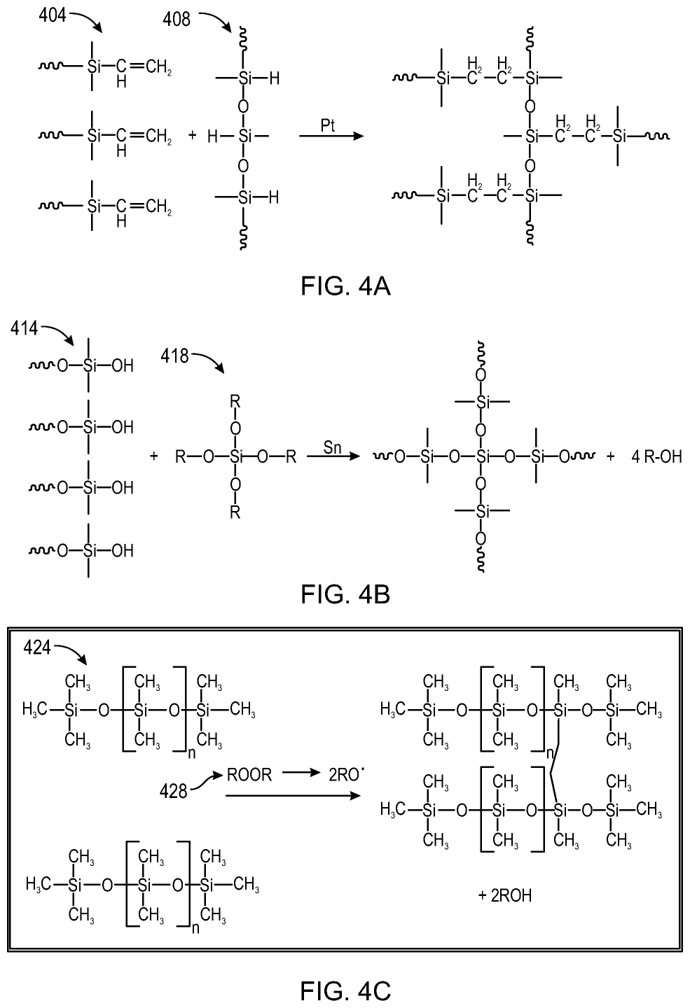

FIG. 4A is a schematic illustration of a chemical reaction showing how a silane coupling agent 404 is bonded to a silicone gel 408 in some embodiments. In these embodiments, a carbon carbon bond is created. In some embodiments, the bonding is free of byproducts. In some embodiments, a catalyst, such as a small amount of platinum is needed to facilitate the curing. In some embodiments, the silane coupling agent has a functional group with a carbon carbon double bond. The carbon carbon double bond is used to create the carbon carbon bond with silicone.

FIG. 4B is a schematic illustration of a chemical reaction showing how another silane coupling agent 414 is bonded to a silicone gel 418 in some embodiments. In these embodiments, an oxygen silicon bond is created. In some embodiments, the bonding forms byproducts containing OH.

FIG. 4C is a schematic illustration of how a silane coupling agent 424 is bonded to a silicone gel 428 in some embodiments. A free radical and high temperature is used for the curing process. In these embodiments, an oxygen silicon bond is created. In some embodiments, the bonding forms byproducts contain OH.

In some embodiments, the silane coupling agent is transparent. In some embodiments, ethanol or methanol may be used as solvents for the silane coupling agent.

A silane coupling agent may not have been previously used because the application of such a silane coupling agent provided steps that were not previously required. Previously, the edge rings may not have been subjected to the same tensile stresses and thermal conductivity requirements. In addition, a layer of silane coupling agent changes conductivity and therefore may change uniformity. In addition, other primers may be a source of contaminants during plasma processing. In addition, some silane coupling agents may leave clumps after drying. Such clumps would reduce the performance of the gel layer. In some embodiments, the silane coupling agent is colorless and has low viscosity, and forms a uniform layer after drying. In some embodiments, the viscosity of the silane coupling agent is less than 1 millipascal second. In some embodiments, the silane coupling agent is able to be cured using dry air at room temperature. In some embodiments, the temperature for curing the silane coupling agent is in the range of 10° C. to 50° C. In some embodiments, the temperature range for curing the silane coupling agent is in the range of 20° C. to 30° C. Such silane coupling agents do not require additional complicated curing steps at a high temperature. Using a pure silane coupling agent as a primer increases adhesion without unduly increasing contaminants. In some embodiments, the silane coupling agent is applied by brushing.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A chuck system for supporting a substrate in a plasma processing chamber, comprising:
a base plate, comprising:
a substrate support region; and
a shoulder surrounding the substrate support region;
a protective coating on a surface of the base plate, wherein the protective coating covers at least part of the shoulder; and
a layer of a silane coupling agent on the protective coating.

2. The chuck system, as recited in claim 1, wherein the layer of the silane coupling agent has a thickness in a range of a monolayer and 100 nm.

3. The chuck system, as recited in claim 1, further comprising a gel layer on the layer of the silane coupling agent.

4. The chuck system, as recited in claim 3, further comprising an edge ring on the gel layer.

5. The chuck system, as recited in claim 4, further comprising a ceramic plate over the substrate support region.

6. The chuck system, as recited in claim 3, wherein the gel layer comprises silicone.

7. The chuck system, as recited in claim 6, wherein the gel layer has a thickness in a range of 50 mm to 1000 mm.

8. The chuck system, as recited in claim 1, wherein the chuck system is an electrostatic chuck system.

9. The chuck system, as recited in claim 1, wherein the base plate is electrically conductive.

10. The chuck system, as recited in claim 1, wherein the protective coating is a metal oxide containing coating.

11. A method for forming a substrate support for use in a plasma processing chamber, comprising:
providing a base plate, comprising:
a substrate support region; and
a shoulder surrounding the substrate support region;
thermal spraying a protective coating on a surface of the base plate, wherein the protective coating covers at least part of the shoulder; and
depositing a layer of a silane coupling agent on the protective coating.

12. The method, as recited in claim 11, wherein the depositing the layer of a silane coupling agent, comprises brushing on a layer of silane coupling agent.

13. The method, as recited in claim 11, further comprising depositing a gel layer on the layer of the silane coupling agent.

14. The method, as recited in claim 13, further comprising placing an edge ring on the gel layer.

15. The method, as recited in claim 14, wherein the gel layer comprises silicone.

16. The method, as recited in claim 11, wherein the thermal spraying the protective coating thermal sprays a metal oxide containing coating.
